(19) United States
(12) Patent Application Publication
(10) Pub. No.: US 2013/0162882 A1
(43) Pub. Date: Jun. 27, 2013

(54) Method of Manufacturing Plurality of Optical Devices

(71) Applicants: Hartmut Rudmann, Jona (CH); Peter Riel, Bach (CH)

(72) Inventors: Hartmut Rudmann, Jona (CH); Peter Riel, Bach (CH)

(73) Assignee: HEPTAGON OY, Espoo (FI)

(21) Appl. No.: 13/702,337

(22) PCT Filed: Jun. 10, 2011
(86) PCT No.: PCT/CH2011/000140

§ 371 Date: Mar. 1, 2013

Related U.S. Application Data
(60) Provisional application No. 61/354,389, filed on Jun. 14, 2010.

(51) Int. Cl. H01L 31/0232; H04N 5/238; H01L 31/18

(52) U.S. Cl. CPC H01L 31/0232; H01L 31/18; H04N 5/238
USPC 348/336; 438/70; 257/432

(57) ABSTRACT

In accordance with an aspect of the invention, a method of manufacturing, on a waver scale, a plurality of optical devices comprises the steps of providing a wafer scale spacer with a plurality of holes arranged in a hole pattern at the positions of camera modules, providing a wafer scale substrate with an infrared (IR) filter that is patterned to comprise a plurality of IR filter sections, the IR filter sections being arranged in an IR filter pattern that is such that radiation paths through the substrate and onto the camera modules go through the IR filter sections, and stacking the substrate and the spacer on each other with the holes and the filter sections being aligned.

### FIELD OF THE INVENTION

The invention is in the field of manufacturing integrated optical devices with at least one optical element, e.g. refractive and/or diffractive lens, in a well defined spatial arrangement on a wafer scale. Such integrated optical devices are, for example, camera devices, especially for camera mobile phones or optics for camera devices. More concretely, the invention relates a method of fabricating a plurality of integrated optical devices on a wafer scale comprising stacking wafer-scale elements in an axial (or ‘vertical’) direction. The invention further relates to an optical device manufactured by means of such a method.

### BACKGROUND OF THE INVENTION

Manufacturing of—active or passive—optical devices on a wafer scale is becoming increasingly important. A reason is the ongoing trend to make optical devices a low cost mass product. Optical devices, such as cameras or integrated camera optics, are nowadays integrated in a large percentage of any electronic devices manufactured, including mobile phones, computers, etc.

Of special interest are the wafer-scale fabrication processes, where an array of optical elements is fabricated on a large-scale, for example disk-like (“wafer-”) structure, which subsequently to replication is separated (“diced”) into the individual elements. In such wafer-scale manufacturing for example optical lenses are produced by providing a wafer and replicating an array of according refractive (and/or diffractive) optical elements thereon. The array is subsequently diced into the individual lenses, which then are assembled with other lenses and/or an optically active element such as a CMOS or CCD sensor array.

A disadvantage in this is that the individual assembling step is still a time consuming task. Therefore, it has been proposed for example in U.S. Pat. No. 7,457,490 or in WO 2009/076 786, both incorporated herein by reference in their entirety, to assemble the different components on a wafer scale, and to carry out the dicing step only after the wafer-scale assembly. The wafers for this comprise optical, elements in a well defined spatial arrangement on the wafer. Such a wafer scale package (wafer stack) comprises at least two wafers that are stacked along the axis corresponding to the direction of the smallest wafer dimension (axial direction) and attached to one another. At least one of the wafers bears passive optical elements, and the other can comprise also passive optical elements or can be intended to receive other functional elements, such as active optical elements (electro-optical elements such as CCD or CMOS sensor arrays. The wafer stack thus comprises a plurality of generally identical integrated optical devices arranged side by side. In such a wafer-scale assembly process, the corresponding individual components have to be aligned with sufficient accuracy.

A first example of such a stack subsequently diced is a stack of two or more optical wafers. The optical wafers are transparent, wafer-like substrates that comprise arrays of optical lenses and/or other optical elements. The arrays of the optical elements are aligned with respect to each other, so that one or more optical elements of each wafer together with one or more corresponding optical elements of an other wafer forms an optical sub-assembly, which after dicing is an integrated optical device that may form a functional unit (for example a camera optics) or sub-unit (for example a lens sub-assembly of a camera optics).

A further example of a stack subsequently diced is a stack of at least one optical wafer and in addition of an electro-optical wafer that may for example comprise an array of image sensor areas to be aligned with the corresponding array of optical elements, so that so that after dicing the integrated optical device with one or more optical elements of the optical wafer(s) together with one or more corresponding electro-optical elements of the electro-optical (semiconductor) wafer forms a functional unit (such as a camera module) or sub-unit (such as a sensor module for a camera). Some examples of such stacks are for example described in WO 2005/083 789.

In such a wafer stack, the at least two wafers may be separated by spacer means, e.g. a plurality of separated spacers, an interconnected spacer matrix, or a spacer wafer as disclosed in WO 2009/076 786, and optical elements can also be arranged between the wafers on a wafer surface facing another wafer. Thus, a spacer is sandwiched between a top wafer and a bottom wafer. This arrangement may be repeated with further wafers and intermediary spacers.

One potential problem of wafer-scale assemblies is the dicing process, i.e. the process of separating the stack into the individual optical devices. This dicing process may be carried out by mechanical means (for example like the dicing of semiconductor wafers), for example by a saw-like tool, a milling tool, or potentially also by other means such as laser cutting, water jet cutting, etc.

Often when integrated camera modules or optical modules for camera modules are diced, material loosens and drops into the space between the wafer dices, for example onto the sensor module or onto a lens. This causes a lot of reject cameras or optical modules and as a consequence increases the cost.

### SUMMARY OF THE INVENTION

It is an object of the invention to provide an improved method and an improved optical device that overcomes drawbacks of prior art methods and optical devices. An optical device in this may be a camera or an optical module for a camera that is suitable of directing incoming radiation in an appropriately focused manner onto a sensor device of the camera.

In accordance with an aspect of the invention, the method comprises the steps of providing a wafer scale spacer with a plurality of holes arranged in a hole pattern at the positions of camera modules, providing a wafer scale substrate with a wavelength selective filter, such as an infrared (IR) filter that is patterned to comprise a plurality of filter sections, the filter sections being arranged in a filter pattern that is such that radiation paths through the substrate and onto the camera modules go through the filter sections, and stacking the substrate and the spacer on each other with the holes and the filter sections being aligned.

In general, the filter will be traversed by the optical path. In this, the optical path is the sum of all ray paths that go through the optical components, generally through a system aperture, and onto the sensor module, thus the sum of all ray paths that contribute to the image to be generated.

In addition to the filter sections, the substrate may comprise an array of lenses or other optical elements on one side or on both sides thereof. The optical elements will be aligned with the filter sections and, after the stacking step, with the holes. Generally, the optical elements will be aligned with the filters in a manner that light passing through the optical elements to be directed to the sensor module of the camera has to pass through the filter.

Generally, the filter sections are separate and not contiguous with each other.

In accordance with an embodiment of the invention, the filter sections of a same filter layer will have an identical composition, i.e. they may be of a common layer that is structured horizontally (in the layer plane) to yield the filter sections, and the transmission characteristics for a radiation beam that impinges on a filters section from a given angle may be identical. The filter sections have identical or different shapes but identical vertical structures.

In accordance with an embodiment, the filter sections will be IR filter sections.

In accordance with an other embodiments, the filter sections may be color filter sections. Different color filter sections may have an identical composition, or there may be different color filter sections with different transmission characteristics. The description of embodiments of the invention that follows hereinafter primarily mentions IR filters. However, the teaching also applies to color filters.

An IR filter is a common feature of camera modules used to avoid disturbing effects of infrared radiation on the image quality. In prior art wafer scale assemblies, one of the wafers 1 was provides with an IR filter layer 11, as depicted in FIG. 1. FIG. 1 shows a to-be-assembled stack of a first wafer 1 with replicated lenses 3, a spacer wafer with a plurality of through holes 6 aligned with the first wafer lenses 3, and a second wafer 2 with a plurality of second wafer lenses 7 aligned with the first wafer lenses 3 and the through holes. The alignment of the lenses with respect to each other is often more critical than the alignment of the through holes 6 with respect to the lenses. The dashed lines illustrate the position where the stack, after being assembled and potentially after further manufacturing steps, is diced.

Instead of a stack of two passive optical wafers 1, 2 each carrying lenses, the stack may also be a stack of an optical wafer and a wafer with sensor modules, with a spacer wafer there between.

Such configurations feature the disadvantage that the wafer 2 carrying the IR filter layer 11—the wafer 2 is often thin and flexible—tends to bow when subject to temperature changes. Such a wafer bow is not acceptable for wafers scale assemblies of multiple wafers.

In order to avoid the problem of wafer bow, an other prior art approach, illustrated in FIG. 2, proposes to arrange two IR filters with 11.1, 11.2 with approximately equal thicknesses on the two surfaces of a wafer 1. The IR filters 11,1, 11.2 may have a reduced filtering capacity compared to a single IR filter, so that their effect taken together equals a single IR filter as in the arrangement of FIG. 1. For example, if the IR filter is made up of a plurality of alternating layers, the sum of the number of layer pairs of the two filters 11.1, 11.2 may correspond to the number of layer pairs of a single IR filter in a one-filter arrangement.

The resulting symmetry avoids the problem of wafer bow. FIG. 2 shows this for an optical wafer 1 with lenses 3 to be assembled with a sensor module wafer 9 with the sensor modules 8.

However, it has been found by the inventors of the present invention that the IR filter at the interface to the spacer wafer tends to be a cause for the observed reliability problems caused by the dicing process, for example in later reliability testing. Dicing was observed to cause small cracks 21 in the IR filter layer where the same may be subject to forces because it the spacer wafer is attached to it (a potential adhesive layer is not illustrated in FIG. 3, and is not illustrated in subsequent figure either). Such cracks 21 are able to propagate from the dicing strait—the outer surface after dicing—to the inside and then cause material 22 dropping onto the sensor 8, as illustrated in FIG. 3. Material dropping in the hollow space 23 that results after assembling the wafers and dicing is also a problem if none of the assembled wafers is a sensor module wafer, because there is no possibility to remove the material from the hollow space, and the material may influence the quality of the image made by the camera that comprises the optical module.

The approach according to the aspect of the invention solves the problems of these prior art approaches. The patterning if the IR filter makes possible that the IR filter is kept away from the interface between the spacer wafer and the optical wafer.

In accordance with a first option, the patterned IR (or color) filter is arranged at the wafer surface to which the spacer wafer is attached. The patterning is preferably so that the in-plane extension of the IR filter sections is within the cross section of the holes of the spacer wafer. In addition, a—patterned or not patterned additional IR filter may also be present elsewhere, for example on the surface of the substrate other than the one on which the first, patterned IR filter is present, or on a surface of a second transparent substrate.

In accordance with a second option, the patterned IR (or color) filter is arranged at the wafer different from the wafer surface to which the spacer wafer is attached. The IR filter pattern is so that it corresponds to the hole pattern, but the IR filter sections may be larger than the hole cross section. Again, further IR filters are possible.

Combinations of the first option with the second option are possible and are discussed further below.

In preferred embodiments, the pattern of the IR (or color) filter section corresponds to the pattern of the spacer holes, i.e. the pitch of both patterns is the same, and generally one IR filter section per hole is present. However, in embodiments of the second option it is also possible to provide filter sections that each correspond to a plurality of modules, so that the filter sections each cover more than one hole.

The invention also pertains to an optically transparent wafer-scale substrate with an IR filter applied to a surface, the IR filter comprising a plurality of IR filter sections that are arranged in an array.

The IR filter sections are islands in the sense that they are not contiguous with each other.

The invention further pertains to a camera that may be manufactured by the process. A camera comprises an optical axis and a sensor module, at least one spacer, and at least one transparent substrate carrying an optical element. The sensor module, the spacer, and the substrate with the optical element are stacked vertically with respect to the optical axis. At least one wavelength selective filter, such as an IR filter, adheres to the substrate. The substrate has a first area perpendicular to the optical axis, and the filter has a second area that is smaller than the first area. Light impinging on the camera that is directed to the sensor module traverses the filter. The IR filter may be structured laterally so that it there is no overlap with areas in which the spacer adheres to the substrate.

The optical means of the camera may further include an aperture. The aperture is formed by a hole in a non-transparent aperture layer, such as a Chromium based layer. The aperture, of course, is aligned with the lenses or other optical means. Optionally, a second non-transparent layer, vertically spaced from the aperture layer, may be present, the second non-transparent layer having a hole that forms, together with the aperture, a baffle. Such an optional second non-transparent layer may also be structured to laterally not reach to the surface. In an embodiment, the wavelength selective filter, for example the IR filter, has an overlap with the aperture layer. For example, the wavelength selective filter has a peripheral portion that is peripheral of the aperture and surrounds the aperture.

In an embodiment, the camera comprises a plurality of transparent substrates and a plurality of spacers. In this, the wavelength selective filter, or, if a plurality of wavelength selective filters is present, at least one of the wavelength selective filters, may be present adhering to the substrate closest to the object-side. For example, an IR filter of the camera may consist of one or two IR filter sections adhering to the object-side substrate.

The term ‘wafer’ in this text is not to be understood to be restricting in terms of the shape of the wafer-scale substrate, but refers to any substrates suitable for a plurality of optical lenses (or a plurality of sensor modules, respectively) to be subsequently separated into the individual components. ‘Wafer’ or ‘Wafer scale’ in this text may more particularly refer to the size of disk like or plate like substrates of sizes comparable to semiconductor wafers, such as disks or plates having diameters between 5 cm and 40 cm. A wafer or substrate in the meaning used in this text is a disc or a rectangular plate or a plate of any other shape of any dimensionally stable material; if the wafer is an optical wafer the material is often transparent. The diameter of a wafer disk is typically between 5 cm and 40 cm, for example between 10 cm and 31 cm. Often it is cylindrical with a diameter of either 2, 4, 6, 8 or 12 inches, one inch being about 2.54 cm. The wafer thickness of optical wafers is for example between 0.2 mm and 10 mm, typically between 0.4 mm and 6 mm. Although preferably the wafers have the shapes of circular discs, like semiconductor wafers, other shapes such as approximately rectangular shapes, hexagonal shapes etc. are not excluded. The term ‘wafer’ in this text is generally not to be interpreted restricting in terms of shape.

### BRIEF DESCRIPTION OF THE DRAWINGS

Principles of the invention as well as embodiments thereof will be explained in more detail in the following text with reference to the attached drawings. In the drawings, same reference numerals denote same or analogous elements. The drawings are all schematic and not to scale. They show:

FIGS. 1 and 2 Prior art wafers stacks;

FIG. 3 A camera module manufactured by dicing a wafer stack as depicted in FIG. 2 into individual elements;

FIGS. 4-7 Embodiments of camera modules according to the invention;

FIG. 8 A wafer stack for a camera module as depicted in FIG. 6;

FIG. 9 A view of a transparent wafer with IR filter sections;

FIG. 10 A top view of a transparent wafer with IR filter sections in an alternative arrangement; and

FIG. 11 A flowchart of a method of manufacturing camera modules.

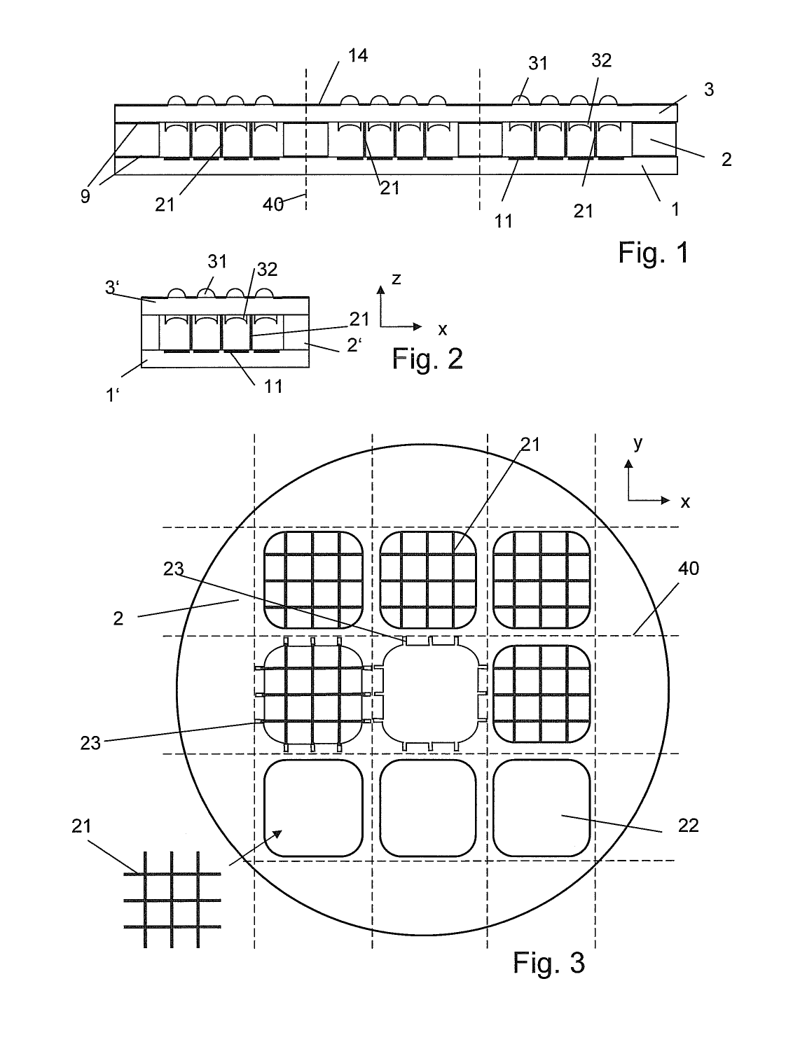

### DESCRIPTION OF THE PREFERRED EMBODIMENTS

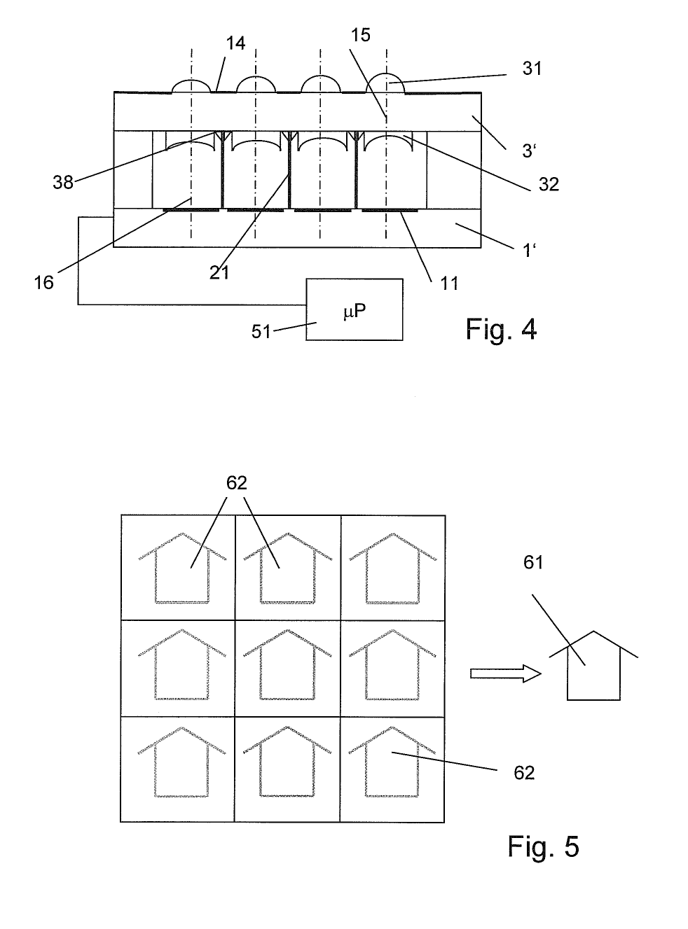

In all of FIGS. 4-8, the shown embodiments comprise a single optical transparent substrate 1 with two replicated lenses 3 (or sub-lenses) acting, together as a camera lens for the sensor module 8 of the camera. The transparent substrate 1 is mounted to the camera module 8 by means of the spacer 5. The teaching explained referring to these figures may, however, also be used for stacks comprising two or more substrate with one or two replicated lenses—or other optical means—adhering to their surface.

In the depicted embodiments, the structured wavelength selective filter is an IR filter. The approach of structuring the IR filter may be used for any substrate carrying the IR filter or one of the IR filters, whether this substrate is the first substrate (seen from the object side) or not. If IR filters are applied to different substrates, the teaching may pertain to one or more or all of these substrates.

The camera module depicted in FIG. 4 comprises, on the first, transparent substrate 1, a first IR filter 11.1 and a second IR filter 11.2. The second IR filter is on the surface of the substrate that faces towards the spacer 5. A chromium aperture 31 surrounds the object-side lens and keeps light from entering the camera on other paths than through the optical system constituted by the lenses. In addition to the aperture, the optical module may have means for preventing light from entering the camera from lateral directions (referring to the optical axis 30).

The embodiment of FIG. 4—as well as the embodiments of the following figures—comprises an optional, second chromium layer 32 that is ring-shaped to form, together with the chromium aperture, a baffle and to keep the interface between the spacer 5 and the substrate 1 free of chromium.

In the figures, the chromium aperture and baffle layers are shown at a small distance from the support (substrate or IR filter) they adhere to. This is for illustration purposes only to clearly distinguish the CR layers from the IR filter. In practice, of course, the CR layer will be in direct contact with the support.

The second IR filter 11.2 during the manufacturing of the camera module is structured to comprise one IR filter section per module. It is arranged so that it does not laterally reach to the dicing location or, preferably, that is does not extend to the region where the spacer 5 is to contact the substrate 1. In this way, the interface between the spacer 5 and the substrate is kept free of IR filter material.

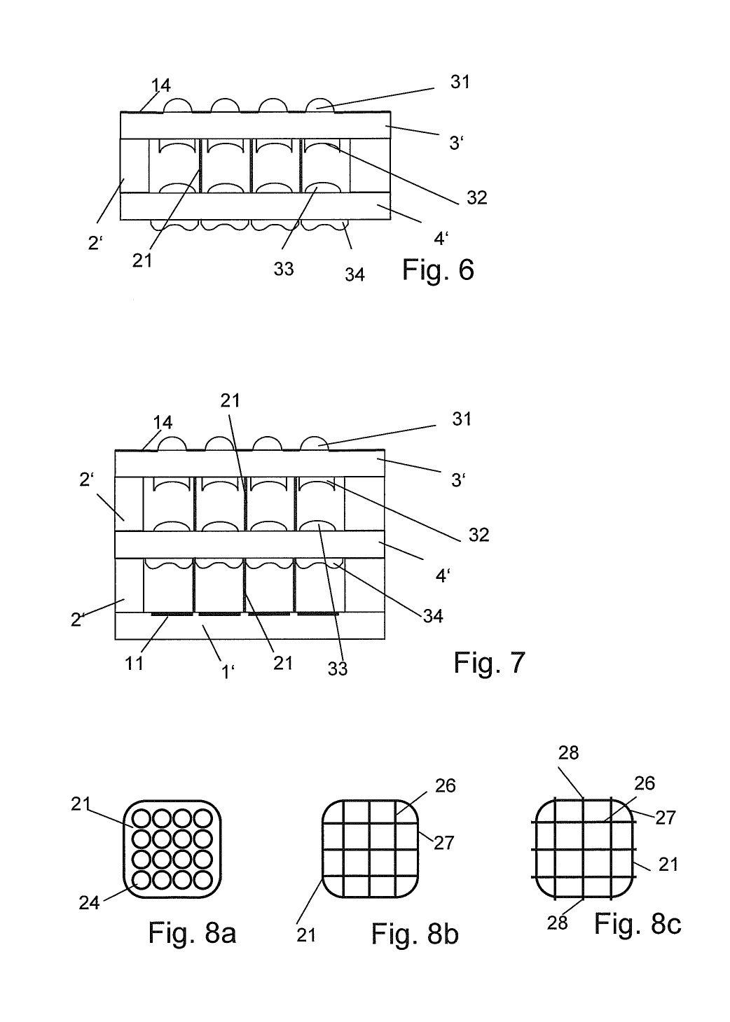

While the embodiment of FIG. 4 solves the problem of material dropping in the hollow space 23, some residual wafer bow may result from the fact that the first IR filter 11.1 in the wafer stack (before dicing) is contiguous and the second is not. Compared to the prior art, this wafer bow tendency is potentially reduced, because the first IR filter may be thinner than a single IR filter, because of the presence of the second IR filter. If this residual wafer bow is still a problem, it is possible to eliminate the contiguous (before dicing) IR filter entirely, and to potentially make the remaining, structured filter accordingly thicker, as depicted in FIG. 5. In the embodiment of FIG. 5, the IR filter 11 is on the side of the substrate that faces the spacer. It is structured so that the interface between the substrate and the spacer is free of IR filter material. It is also possible to arrange the IR filter on the side of the substrate that faces away from the spacer and faces to the object, as illustrated in FIG. 6. In the embodiment of FIG. 6, the IR filter 11 may (but need not) laterally extend further than the through hole 6 in the spacer wafer, because an overlap with the wafer/spacer interface does not have the disadvantages of an overlap of an IR filter on the side of the spacer-facing side of the optical wafer. Also in the embodiment of FIG. 6 the IR filter should, on a wafer scale, essentially not be contiguous but be made up of individual IR filter sections.

The embodiment of FIG. 7 comprises, on each of the two sides of the wafer, an IR filter section 11.1, 11.2. The embodiment of FIG. 7 thus is a combination of the approaches of FIG. 5 and FIG. 6.

FIG. 8 shows the embodiment of FIG. 6 on a wafer scale prior to dicing. FIG. 8 does not show the Chromium layers; generally at least an aperture layer having aperture openings for each camera module and optionally a further non-transparent layer with openings will be present. The dashed lines in FIGS. 8-10 illustrate the locations where dicing takes place.

FIG. 8 illustrates that the IR filter sections 11 of neighboring camera modules are not contiguous with each other on the wafer scale. Further, in the depicted embodiment the IR filter sections do not laterally reach to the dicing locations.

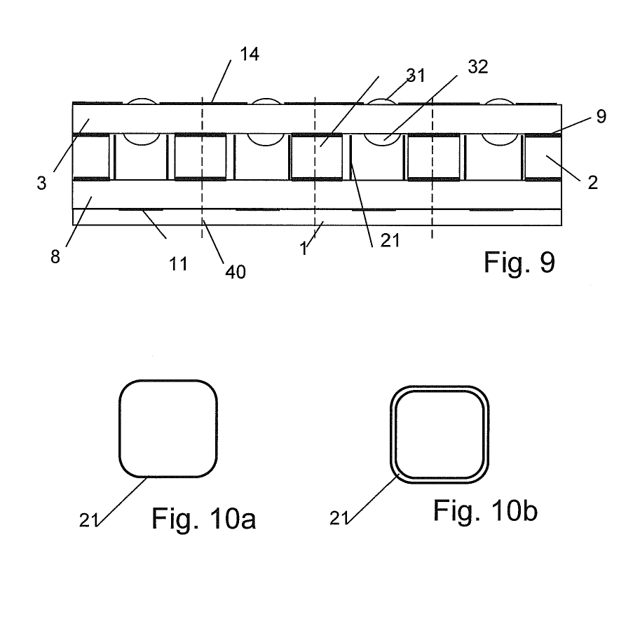

FIG. 9 shows an optical wafer for the embodiment of FIGS. 6 and 8. The IR filter sections may be circular, with the optical axis being in the center of the filter section. Also other IR filter section shapes are possible, such as rectangular, or shapes adapted to a particular optical symmetry, etc.

FIG. 10 shows a variant of the embodiment of FIGS. 6, 8, and 9 where the filter sections 11 extend to a plurality of camera modules. More specifically, each filter section on the wafer scale covers a group of neighboring camera modules. In the depicted embodiment, four camera modules are covered by each filter section. Also in this embodiment, the filter sections are not contiguous. As long as the filter sections are not too extended, the problem of wafer bow will be solved by the fact that the individual filter sections are spaced from each other.

In all embodiments, the following may hold:
the IR (or color) filter(s) may be (an) IR (or color) filter(s) of a kind known in the art, for example, the IR (or color) filter(s) may comprise a plurality of layers of different indexes of refraction. The plurality of layers may be include alternating first and second layers of varying thicknesses. As an example, the IR filter(s) may comprise a sequence of Silicon-Oxide and Titanium-Oxide layers.
The transparent substrate may be a glass wafer or an other transparent thin sheet of material with two for example plane parallel large surfaces;
The lenses may be lenses manufactured by wafer-scale UV replication, as for example described in WO 2004/068 198, WO 2007/107025 and various other documents;
The aperture and, if present, the additional non-transparent layer may be made from a Chromium based layer, as for example described in WO 2009/076 787;
The spacer may be transparent or non-transparent, and it may be made of any suitable material, including plastics (such as a spacer of the kind described in WO 2009/076 786, of glass, ceramics, a metal, etc.

Generally, quantities like material compositions are not critical for carrying out the invention, and the skilled person will know many variants of material compositions suitable for manufacturing the camera modules.

FIG. 11 shows a flowchart of an embodiment of the invention.

While the invention has been described referring to embodiments in which the filter is an IR filter, the teaching may also be applied to embodiments with other wavelength selective filters. For example, the filter sections may be color filter sections of equal or different colors. In a special embodiment, the filters may be color filters of sub-cameras for capturing sub-images of red, green, or blue color. The sub-images may together be combined to a color image. In contrast to prior art approaches, where the sensor itself is covered by the respective color filter, the approach according to the ‘color filter’ embodiments of the invention features the advantage that the filter is at more distance to the sensor. Minor faults of the filter, such as tiny scratches etc. are therefore in contrast to the prior art embodiments less of a problem because they are leveled out by the optical means through which the light is directed before it impinges on the sensor.

1. A method of manufacturing, on a wafer scale, a plurality of optical devices being camera modules with a sensor module or being optical modules for camera modules with a sensor module, the optical devices each defining an optical path, the method comprising the steps of:
providing a first wafer scale substrate comprising a pattern of lenses and comprising a wavelength selective filter that is patterned to comprise a plurality of filter sections,
providing a wafer scale spacer with a plurality of holes arranged in a hole pattern that corresponds to the pattern of lenses;
stacking the first substrate and the spacer on each other with the holes and the lenses being aligned, and with the filter sections being arranged and dimensioned so that the respective optical path traverses the respective filter section, the step of stacking yielding a wafer scale stack, and
separating the wafer scale stack into the optical devices.

2. The method according to claim 1, comprising, prior to the step of separating the wafer scale stack, the further step of providing a second wafer scale substrate and stacking the second wafer scale substrate and the spacer on each other.

3. The method according to claim 2, wherein the second wafer scale substrate is a transparent optical substrate with an array of optical elements.

4. The method according to claim 2, wherein the second wafer scale substrate is an electro-optic wafer comprising an array of the sensor modules.

5. The method according to claim 3, comprising the further steps of providing a second spacer and stacking the second spacer and the wafer scale stack onto each other, prior to the separating step.

6. The method according to claim 1, wherein the filter is on a surface of the first substrate that faces an object side and faces away from the spacer.

7. The method according to claim 6, wherein the first wafer scale substrate comprises a second filter comprising a plurality of filter sections on a second surface of the first substrate, which second surface faces an image side and faces to the spacer.

8. The method according to claim 1, wherein the filter is on a surface of the first substrate that faces an image side and faces to the spacer.

9. The method according to claim 8, wherein the first wafer scale substrate comprises a second filter on a surface of the first substrate that faces an object side and faces away from the spacer.

10. The method according to claim 1, wherein each optical device comprises one filter section spaced from filter sections of the other optical devices, or a plurality of filter sections spaced in a direction corresponding to a propagation direction along the optical beam path, each spaced from filter sections of the other optical devices.

11.-15. (canceled)

16. A wafer scale optical substrate, comprising a substrate body of an optically transparent material with two essentially plane parallel surfaces, and further comprising a wavelength selective filter applied to a first one of the surfaces, the filter comprising a plurality of filter sections that are mutually spaced from each other and are arranged in an array and which are color filters of sub-cameras for capturing sub-images of red, green, or blue color.

17. A camera comprising a sensor module and an optical system defining an optical axis, the camera comprising at least one spacer, and at least one transparent substrate of the optical system, the substrate carrying an optical element, wherein the sensor module, the spacer, and the substrate with the optical element are stacked vertically with respect to the optical axis, wherein at least one filter adheres to the substrate, wherein the substrate has a first area perpendicular to the optical axis, wherein the filter has a second area that is smaller than the first area and wherein an optical path defined by the optical system and the sensor module traverses the filter, wherein the filter comprises a plurality of filter sections which are color filters of sub-cameras for capturing sub-images of red, green, or blue color.

18. The camera according to claim 17, wherein the optical system further comprises an aperture formed by a hole in a non-transparent layer.

19. A method of manufacturing a color image, the method comprising:
capturing sub-images of red, green, and blue color, respectively, by means of a camera according to claim 17; and
combining the sub-images to the color image.
